(19) United States
(12) Patent Application Publication
(10) Pub. No.: US 2011/0014734 A1
(43) Pub. Date: Jan. 20, 2011

(54) METHOD FOR FABRICATING FLIP CHIP GALLIUM NITRIDE LIGHT EMITTING DIODE

(76) Inventor: Lien-Shine LU, Taipei (TW)

Correspondence Address: Muncy, Geissler, Olds & Lowe, PLLC, 4000 Legato Road, Suite 310, FAIRFAX, VA, 22033, US

(21) Appl. No.: 12/505,991

(22) Filed: Jul. 20, 2009

(51) Int. Cl. H01L 33/00

(52) U.S. Cl. 438/29; 438/42; 438/46; 257/E33.066; 257/E33.067; 257/E33.064

(57) ABSTRACT

The present invention discloses a method for fabricating a flip chip GaN LED, which has a predetermined region on an epitaxial layer for forming a first groove to expose a portion of the substrate, and another predetermined region on the epitaxial layer for forming a second groove to expose a portion of N type GaN Ohm contacting layer. On a side of the first groove, there are a translucent conducting layer, an N type electrode pad, a first isolation protection layer, a metallic reflection layer and a second isolation protection layer sequentially formed on the surface of a P type GaN Ohm contacting layer. On another side of the first groove, a translucent conducting layer, an N type electrode pad, a first isolation protection layer and a second isolation protection layer are sequentially formed on the surface of an N type GaN Ohm contacting layer. The above structure not only can provide a flat surface for electrical connection of the P type and N type electrode pads with the circuit board, but also to keep the metallic reflection layer from conducting electricity to avoid increasing the forward voltage and the power consumption, and accordingly to promote the light emitting performance of the LED.

### BACKGROUND OF THE INVENTION

1. Field of the Invention

The present invention relates to a method for fabricating a flip chip Gallium Nitride (GaN) light-emitting diode (LED); and more particularly to securely install a flip chip LED onto a heat conducting substrate with a large heat dissipation area, and also provide a GaN LED bead with the high light-emitting efficiency and reliability.

2. Description of Related Art

There are a variety of styles and types of light emitting devices available on the market. Lower power consumption and small size LED is more popular. LED is widely used in flash lights, bulletin board, auxiliary indirect lights and backlight source in LCD panel, and one made of the GaN plays a better role.

The present commercial white light uses the GaN LED, which emits blue light to mix with the florescence powder emitting yellow, green or red light wave. However, heat conducting ability of the sapphire substrate is the cause to adversely affect the life span and reliability due to heat. Approximately 50 to 60 percents of the emitted light will be transferred into heat energy. Nevertheless, mixture of the florescence powder and epoxy, which are mixed in a certain ratio, which is used to cover and surround the LED bead causes accumulation of internal heat to reduce the light emitting efficiency and shorten the life span. This would further causes damage due to overheating. Therefore, means for effectively and promptly guiding the heat flow and to disperse the internally accumulated heat to external in order to cool down the temperature therein is crucial for the light emitting efficiency and reliability of the light emitting device. Some products use metallic substrate with high heat dissipation ability to coordinate with the heat pipe or plate applied as the heat dissipation element, but usually the size and the weight of the LED have to be compromised.

Referring to FIG. 11, sapphire substrate A1, N type GaN Ohm contact layer A2, light emitting layer A3, P type GaN Ohm contact layer A4, translucent conducting layer A5 are currently known for its heat dissipation effect and increasing the light emitting efficiency. P type electrode pad A6 is formed on the translucent conducting layer A5 and the N type GaN Ohm contact layer A2, N type electrode pad A7, to use a side of the non-epitaxial layer of the sapphire substrate A1 to securely position onto a rack A8 with the isolating gel or the conducting gel, further to electrically connect a metallic wire A9, for example gold wire or aluminum wire, to a external pin A10 with the florescence powder evenly spread covering over the gel. The light emitted by the light emitting layer A3 has to transmit through the florescence powder and the gel coverage bypassing a side of the P type electrode pad A6 and further penetrate through the translucent conducting layer A5. However, the P type electrode pad A6 covers the partial light emitting surface and reduces the light emitting efficiency of the LED.

For overcoming the defect of the electrode pad A6 covering the partial light emitting surface to adversely affect the light emitting efficiency, referring to FIG. 12, one prior art proposes using a flip chip to increase the valid light emitting area, and the GaN LED including a buffer layer B2 and a N type GaN Ohm contact layer B3 on a sapphire substrate B1, and a light emitting layer B4 and a P type GaN Ohm contact layer B5 at the central region. The P type GaN Ohm contact layer B5 is connected to the external heat conducting substrate through a P type electrode pad B6, and the two sides of the light emitting layer B4 include an N type electrodes B7. One of the N type electrodes B7 is connected to the external heat conducting substrate through an N type electrode pad B8. Although a main light outputting face B11 doesn't have any defect of covering light, however, the structure thereof is designed to use the P type electrode pad B6 and the N type electrode pad B8 made of the metallic material to reflect, and the light emitting efficiency is poor due to the characteristic of the metallic electrode pad which can easily increase the forward voltage.

Referring to FIG. 13, another prior art uses a heat dissipation block C3 between a LED bead C1 and welding points C11, C21 of a circuit board C2, for example a gold bead or a gold-tin block process, to electrically connect and conduct heat. However, the process is more expensive. Furthermore, the electrode pad of the conventional flip chip LED functions for the electrical connection with the circuit board and for reflecting the light from the light emitting layer to the sapphire substrate, but the metallic characteristic of the electrode pad easily increases the forward voltage to adversely affect the light emitting efficiency. Even though the prior art discloses that the metallic reflection layer can be formed on the circuit board, such structure causes more light attenuation due to the longer distance between the light emitting layer and the metallic reflection layer.

Referring to FIG. 14, another prior art discloses a sapphire substrate D1, a N type GaN Ohm contact layer D2, a light emitting layer D3, a P type GaN Ohm contact layer D4, a translucent conducting layer D5 and a conducting metallic reflection layer D6. The N type GaN Ohm contact layer D2 and the translucent conducting layer D5 are respectively connected to a circuit board D8 through the electrode D7 and the conducting metallic reflection layer D6; a polyimide isolation layer D9 is formed in a groove therein in order to prevent the electrical connection between the electrode D7 and the conducting metallic reflection layer D6 and to reduce the possible current leakage caused by the conducting metallic reflection layer D6. However, there are difficulties for precisely disposing the polyimide isolation layer D9 into the groove and without affecting the corresponding surface height of the electrical connection between the electrode D7 and the conducting metallic reflection layer D6, and when the horizontal level has the over volume difference, the electrical connection between the LED and the circuit board can cause the reduction in the yield.

Referring to FIG. 15, another prior discloses a structure of the flip chip GaN LED, which comprises a first epitaxial layer E1 and a second epitaxial layer E2 on the epitaxial layer, thus to maintain the similar horizontal height of the surface of a P type electrode pad E3 and an N type electrode pad E4. For reducing the contact resistance between the N type electrode pad E4 and the second epitaxial layer E2, the N type electrode pad E4 has to extend to reach out having an Ohm contact with an N type GaN Ohm contacting layer E21. Although such technology enables to maintain the same height for the P type electrode pad E3 and the N type electrode pad E4 as well as to have a easier connection with the circuit board, and a metallic reflection layer E5 is disclosed therein, the above defect of increasing the forward voltage still can't be resolved since the metallic reflection layer E5 is positioned surrounding a conducting layer E6 to participate the electrical conduction. Furthermore, the prior art doesn't teach the technique or the process for the flange surface of the groove for adding the isolation beads.

The above structures cause the LED to easily accumulate heat due to overheating and adversely affect the light emitting efficiency. The use of polyimide isolation layer to reduce the power consumption of the LED still has defect of poor heat dissipation effect, and even causes height difference between the P type and N type electrode pads to affect the electrical connection with the circuit board, and accordingly to cause the reduction of the yield.

Therefore, for overcoming the above defect, the present invention provides a novel structure and a method for fabricating a flip chip LED based on the long time research and study in the field of the LED related products to improve design and to solve the above defects.

### SUMMARY OF THE INVENTION

An object of the present invention is to provide a method for fabricating a flip chip GaN LED.

According to an aspect of the present invention, to solve the above conventional defects of due use of metallic reflection layer for reflecting light and conducting electricity increasing the forward voltage, and further increasing power consumption, heat generation and reducing the light emitting efficiency, a first isolation protection layer is disposed on a side of a translucent conducting layer corresponding to the P type GaN Ohm contacting layer, and a metallic reflection layer and a second protection layer are orderly formed on the first isolation protection layer. Further, a P type and an N type electrode pads are connected with the heat conducting substrate by a welding process. This method for fabricating the flip chip LED can exclude the use of metallic reflection layer from the electrical conduction and accordingly reduce the forward voltage of the LED and power consumption, as well as effectively avoid increasing heat to prevent light attenuation caused by the heat accumulation. The metallic reflection layer is formed directly in the LED and has a shorter distance from the light emitting layer, thus the light emitting efficiency can be substantially increased.

According to another aspect of the present invention, a first and the second isolation protection layers are disposed in the second groove to provide a reliable isolation protection between the two sides of the second groove and the epitaxial layer. Thus, the possibility of current leakage or short circuit may be reduced, and therefore the reliability in the flip chip LED fabrication process can be increased.

According to another aspect of the present invention, the combination of the large contact surface of highly conductive conducting gel and the heat conducting substrate not only can reduce the fabrication cost but also speed up the heat dissipation for increasing the productivity. Thus, the light emitting efficiency of the LED and the life span can be increased.

### BRIEF DESCRIPTION OF THE DRAWING

For a more complete understanding of the present invention, reference will now be made to the following detailed description of preferred embodiments taken in conjunction with the following accompanying drawings.

FIG. 1 is a flow chart of a method for fabricating an LED bead according to an embodiment of the present invention.

FIG. 2 is an aspect of an epitaxial layer of an LED bead according to an embodiment of the present invention.

FIG. 3 is an aspect of etching a first groove on an epitaxial layer according to an embodiment of the present invention.

FIG. 4 is an aspect of etching a second groove on an epitaxial layer according to an embodiment of the present invention.

FIG. 5 is an aspect of forming a translucent conducting layer, a P type electrode pad and a N type electrode pad on a surface of the epitaxial layer according to an embodiment of the present invention.

FIG. 6 is an aspect of forming a first isolation protection layer and a metallic reflection layer on a surface of a translucent conducting layer according to an embodiment of the present invention.

FIG. 7 is an aspect of forming a second isolation protection layer according to an embodiment of the present invention.

FIG. 8 is a formation aspect of cutting LED according to an embodiment of the present invention.

FIG. 9 is an aspect of an electrical connection between the LED and a conducting substrate according to an embodiment of the present invention.

FIG. 10 is an aspect of LED having a first V shape groove according to an embodiment of the present invention.

FIG. 11 is an aspect of the structure of a conventional GaN LED.

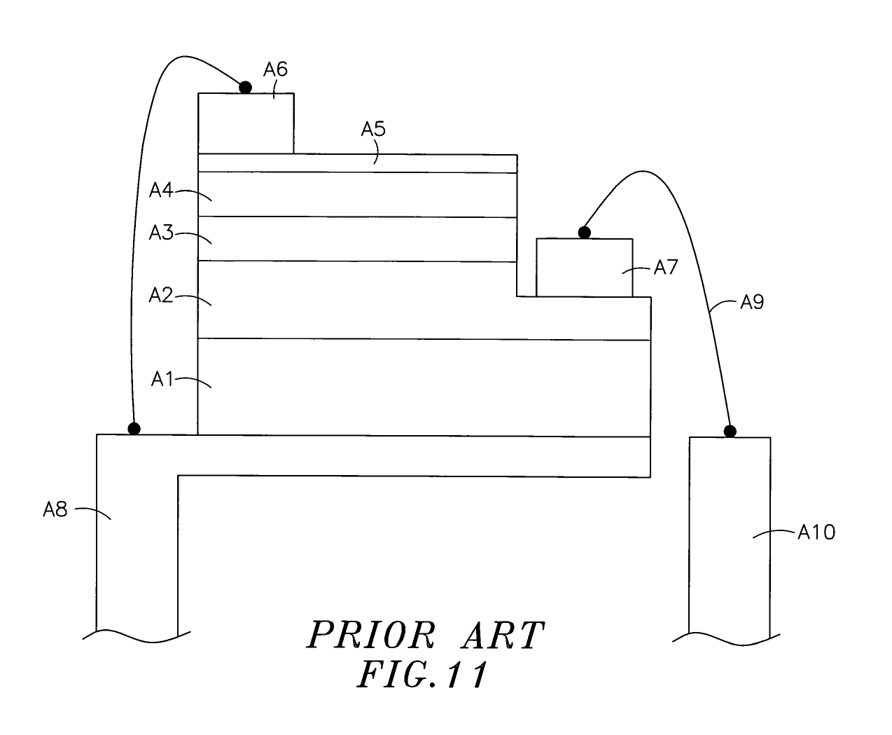

FIG. 12 is an aspect of the structure of a conventional flip chip GaN LED.

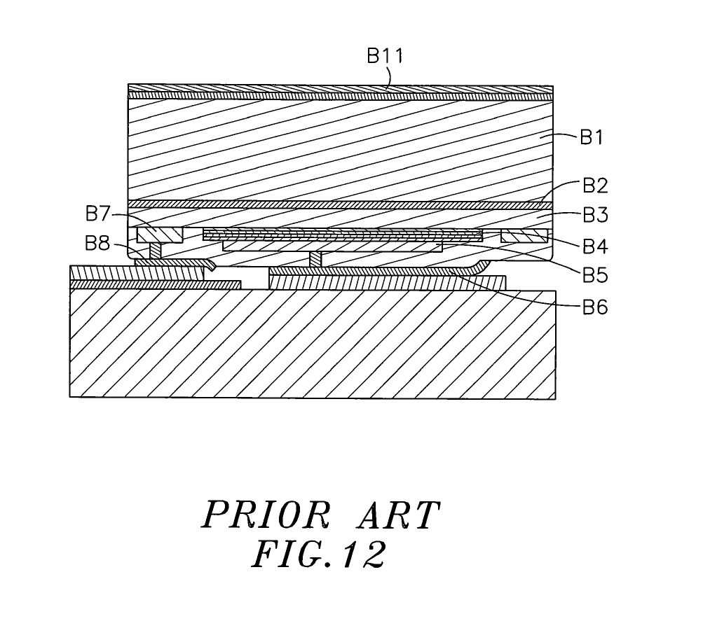

FIG. 13 is an aspect of a structure of another conventional flip chip GaN LED.

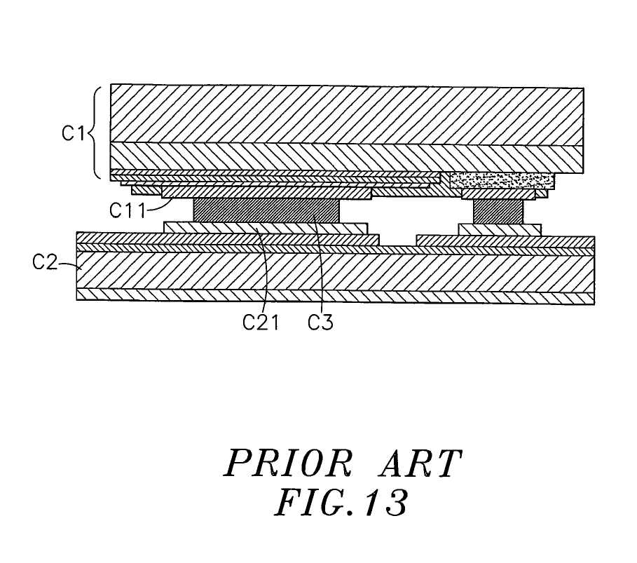

FIG. 14 is an aspect of a structure of another conventional flip chip GaN LED.

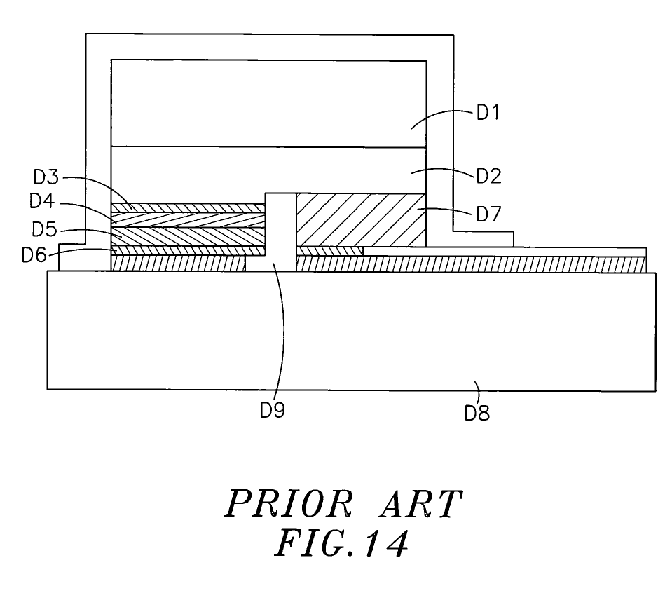

FIG. 15 is an aspect of a structure of another conventional flip chip GaN LED.

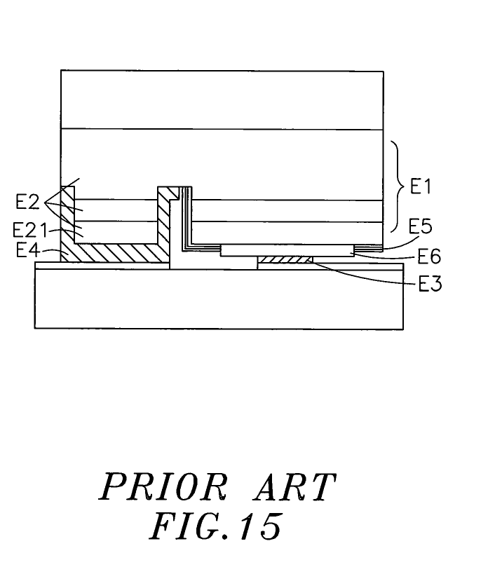

### DETAIL DESCRIPTION OF THE INVENTION

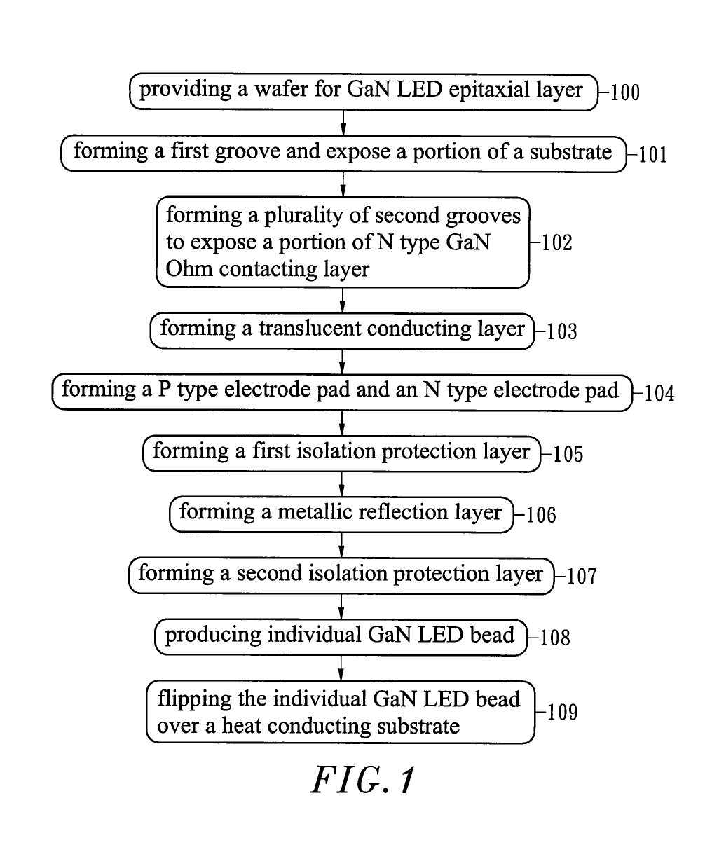

Referring to FIG. 1, a method for fabricating the flip chip GaN LED bead is described as follows.

At step 100, a wafer for GaN LED epitaxial layer 2 is provided.

At step 101, an etching process is performed to form a first groove 101 and expose a portion of a substrate 100.

At step 102, an etching process is performed to form a plurality of second grooves 102 adjacent to the first groove 101 and the outer side to respectively form epitaxial layers 2A, 2B on two sides of a N type GaN Ohm contacting layer 11, and the second groove 102.

At step 103, a translucent conducting layer 14 is formed on a surface of the epitaxial layers 2A, 2B.

At step 104, a P type electrode pad 15 and an N type electrode pad 16 are formed on a portion of the translucent conducting layer 14.

At step 105, a first isolation protection layer 17 is formed over the P type electrode pad 15, the N type electrode pad 16, the first groove 101 and the second groove 102.

At step 106, a metallic reflection layer 18 is formed on a sidewall adjacent to the P type electrode pad 15 and corresponding to the translucent conducting layer 14.

Ata step 107, a second isolation protection layer 19 is formed over the surface of the first isolation protection layer 17 and the metallic reflection layer 18.

At step 108, a grinding, line drawing, breaking and straining is performed by the bead optical characteristic to produce individual GaN LED 1 bead.

At step 109, the individual GaN LED 1 bead is flipped over a heat conducting substrate 3 with a conducting gel 4.

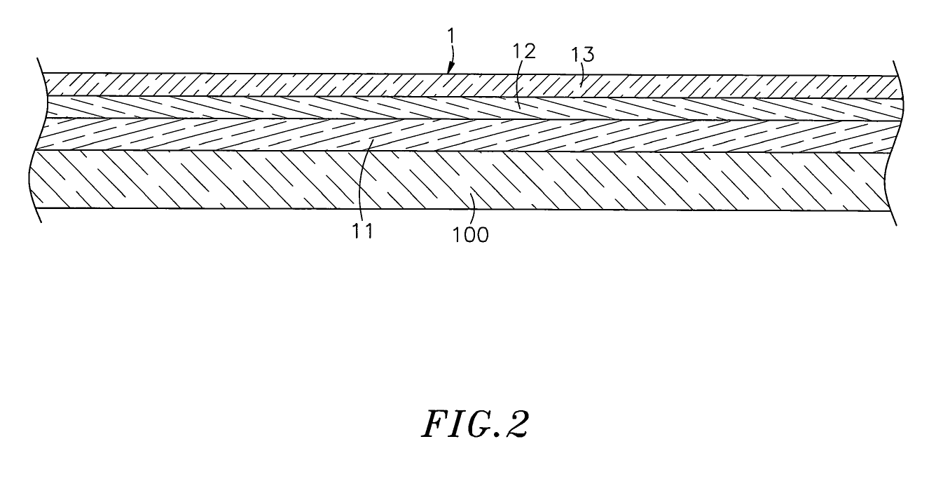

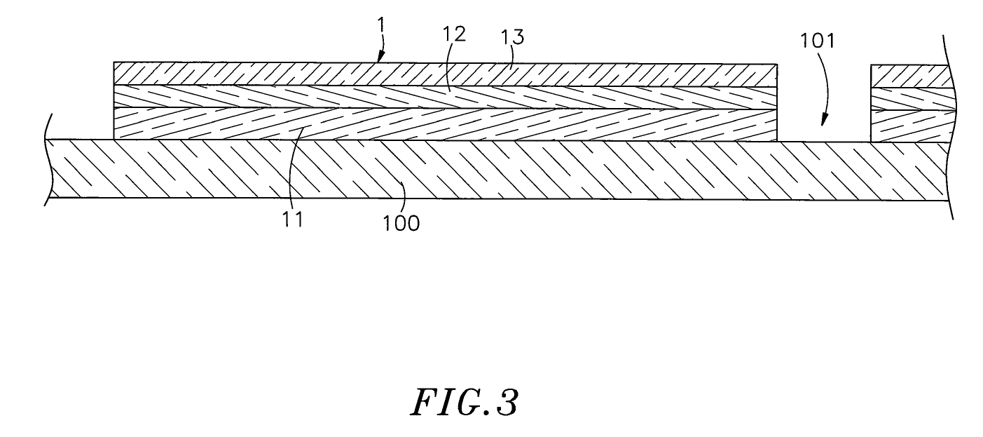

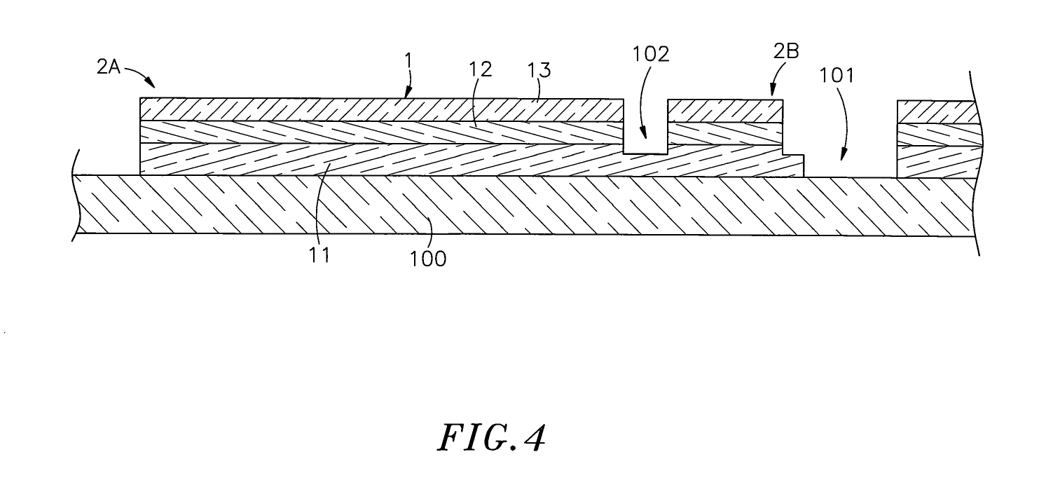

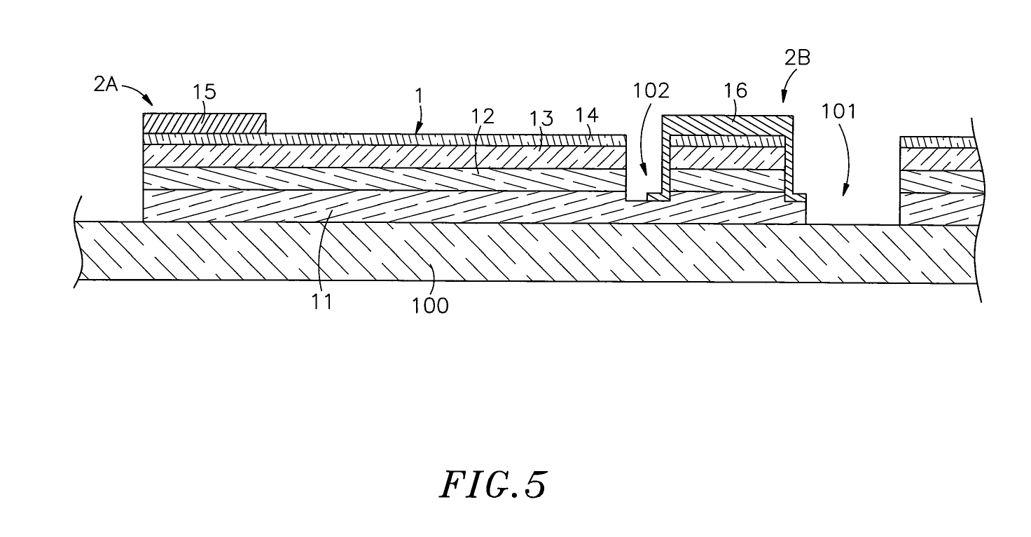

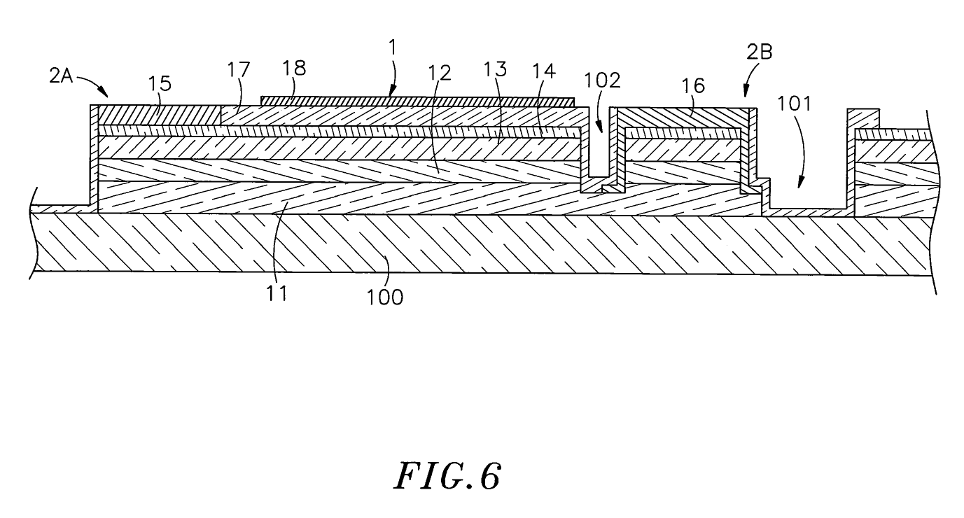

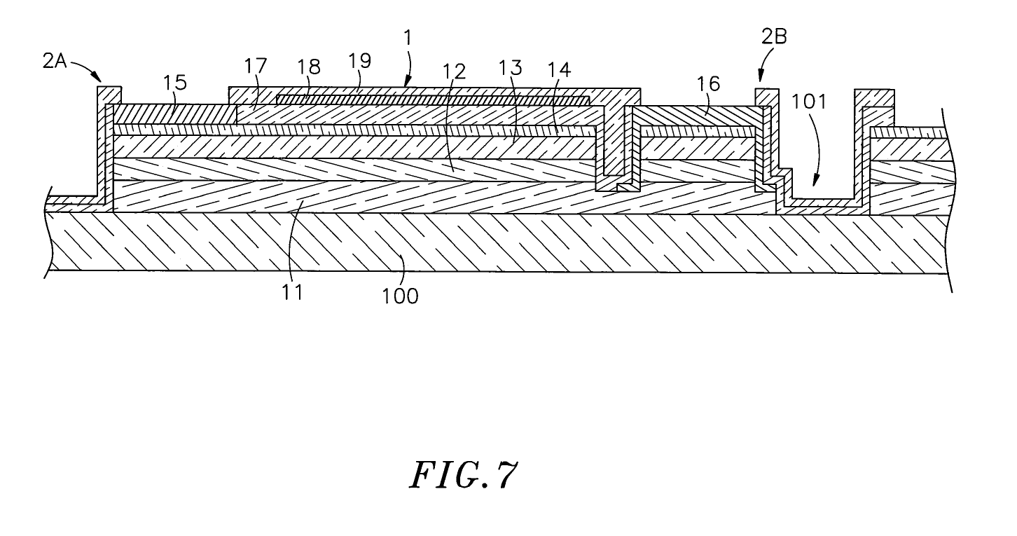

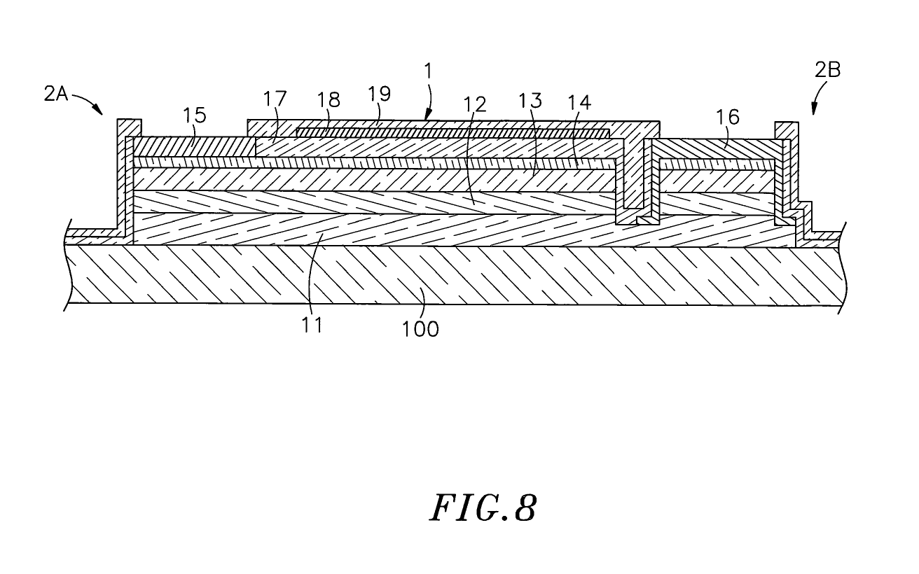

Referring to FIGS. 2 to 8 and still referring to FIG. 1, on the substrate 100, in sequential order, the N type GaN Ohm contacting layer 11, a light emitting layer 12 and a P type GaN Ohm contacting layer 13 are formed. A predetermined region for the mask is provided. The photolithography process may be performed to preserve a region on the epitaxial layer 2 which can be subsequently etched to form the first groove 101 and to expose a portion of the substrate 100. Furthermore, another mask may be used for photolithography process to preserve a region on the epitaxial layer 2 of the wafer which can be subsequently etched to form the second groove 102 and to expose a portion of the N type GaN Ohm contacting layer 11.

Furthermore, an evaporation or a sputtering process is performed on the surface of the P type GaN Ohm contacting layer 13 to form the translucent conducting layer 14. After the photolithography and metal lift-off process for forming the P type electrode pad 15 and the N type electrode pad 16 on the partial surface of the translucent conducting layer 14, a first isolation protection layer 17 is further formed on the surface of the translucent conducting layer 14, the P type electrode pad 15, the N type electrode pad 16, the first and second groove 101, 102. Next, the surface of the P type electrode pad 15 and the N type electrode pad 16 are exposed by performing photolithography, patterning and etching processes. Next, a metallic reflection layer 18 is formed on a sidewall of the first isolation protection layer 17 corresponding to the translucent conducting layer 14 by performing the photolithography, patterning and metal lift-off process. Next, the second isolation protection layer 19 is formed over the P type electrode pad 15, the N type electrode pad 16, metallic reflection layer 18 and the first isolation protection layer 17, and the surface of the P type electrode pad 15 and the N type electrode pad 16 is exposed by performing the photolithography, patterning and etching process. After the above process, the substrate 100 is polished until a desired thickness of less than 100 um is obtained, and then the beads are separated by the laser ruling and breaking process to complete the process of the LED beads.

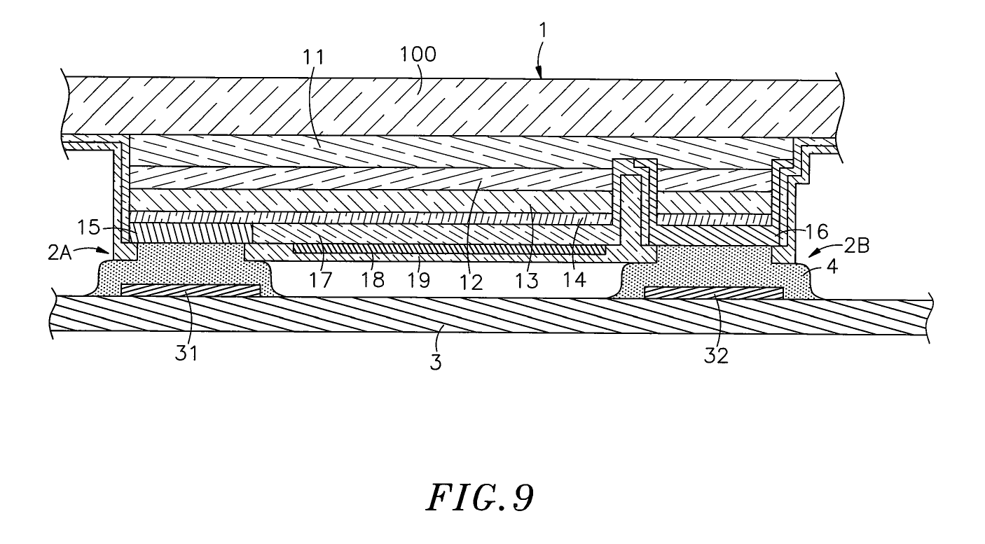

Referring to FIG. 9, the LED 1 is electrically connected to the heat conducting substrate 3 by the flip chip method. The substrate 3 can be made of aluminum, copper or ceramic material with excellent heat conductive characteristics, and the printed circuit with an electrical isolated positive welding pad 31 and a negative welding pad 32. Furthermore, the conducting gel 4, for example the silver gel, tin ball or tin paste, respectively, is formed on the surface of the positive welding pad 31 and the negative welding pad 32 is formed by soldering or adhering process, and the P type electrode pad 15 and the N type electrode pad 16 are respectively connected to the positive welding pad 31 and the negative welding pad 32 through the conducting gel 4. Thereafter, the gel 4 is solidified to complete the flip chip LED. The above LED 1 has the conducting gel 4, for example the silver gel or tin paste, with a large heat dissipation surface area and the heat conducting substrate 3 to directly dissipate the heat. Thus, the conventional defect of using gold wire or metallic protrusion, which has smaller heat conducting face, the poor heat dissipation performance may be avoided, and thus the fabrication cost can be reduced and the fabrication through-put can be increased.

The above substrate 100 can be selected from a group consisting of sapphire, silicon carbide (SiC), zinc oxide (ZnO), magnesium oxide (MgO), gallium oxide (Ga₂O₃), aluminum gallium nitride (AlGaN), gallium lithium oxide (GaLiO), aluminum lithium oxide (AlLiO) or spinel substrate. The translucent conducting layer 14 can be selected from a group consisting indium oxide (In₂O₃), tin oxide (SnO₂), indium molybdenum oxides (IMO), zinc oxide (ZnO), indium zinc oxide (IZO), cellium indium oxide (CeIn₂O₃), indium tin oxides (ITO), a dual structure of nickel (Ni) and gold (Au), a dual structure of platinum (Pt) and gold, the a dual structure of beryllium (Be) and gold. The metallic reflection layer 18 can be selected from a group of metallic materials such as silver (Ag), aluminum (Al) or rhodium (Rh), or combination of nickel, platinum, beryllium, titanium (Ti) and chromium (Cr). The first isolation protection layer 17 or the second protection layer 19 can be selected from a group consisting of silicon oxide (SiO₂), silicon nitride (Si₃N₄), liquefied glass, teflon, polyimide (Pi), aluminum oxide (Al₂O₃), titanium oxide (TiO), tantalum oxide (Ta₂O₅), yttrium oxide (Y₂O₃) or a diamond film. The P type electrode pad 15, the N type electrode pad 16 can be selected from a group consisting combination of titanium and gold, titanium and aluminum, chromium and gold, or chromium and aluminum. The above description is described merely for demonstrating the embodiment of the present invention, all the materials applied in any layer are not intended for limiting the scope thereof; therefore, any changes literally or structurally in the method, the steps and the procedure in order to achieve the same result shall be construed to be within the scope of the present invention.

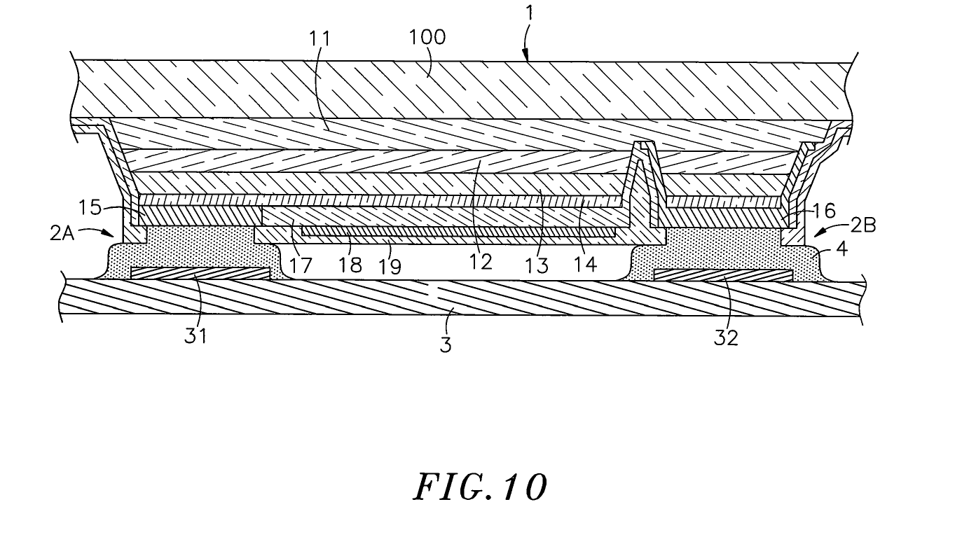

Referring to FIGS. 9 and 10, the first groove 101 and the second groove 102 can be etched into a U shape or V shape, but the shape of groove is merely for demonstrating the embodiment of the present invention; therefore, any changes literally or structurally in the method, the steps and the procedure in order to achieve the same result shall be construed within the scope of the present invention.

The present invention has at least the following advantages.

The first isolation protection layer 17 and the second isolation protection layer 19 are respectively formed on the two sides of the metallic reflection layer 18 to keep the translucent conducting layer 14 and the metallic reflection layer 18 from conducting electricity, thus increase in the forward voltage is effectively avoided and the power consumption caused by the electricity conduction from the metallic reflection layer 18 to prevent affecting light emitting performance of the LED 1. Besides, the metallic reflection layer 18 is directly formed in the LED 1 to directly reflect the light of the light emitting layer 12 and prevent the optical loss.

The epitaxial layer 2 comprises the first groove 101 formed at the predetermined region on the substrate 100, the second groove 102 is formed at another predetermined region, and the epitaxial layers 2A, 2B are formed with the same height, thus the P type electrode pad 15 and the N type electrode pad 16 can be ensure a stable and reliable electrical connection between the LED 1 and the substrate 3 to promote the yield of the LED 1.

The epitaxial layer 2A, 2B formed on the two sides of the second groove 102 has the first and the second isolation protection layer 17, 19 to provide a stable isolation protection between the two epitaxial layers 2A, 2B to effectively prevent the current leakage causing the short circuit in the LED 1 flip chip processing, as well as to maintain the reliability thereof.

The LED 1 of the present invention has the conducting gel 4 as the highly heat conducting material with a large conducting surface area to electrically connect with the heat conducting substrate 3. Thus, heat dissipation efficiency can be increased and accordingly promote the light emitting efficiency of the LED 1.

The LED 1 can effectively and promptly dissipate the accumulated heat through the conducting gel 4 to increase the life span thereof.

While the invention has been described in conjunction with a specific best mode, it is to be understood that many alternatives, modifications, and variations will be apparent to those skilled in the art in light of the foregoing description. Accordingly, it is intended to embrace all such alternatives, modifications, and variations in which fall within the spirit and scope of the included claims. All matters set forth herein or shown in the accompanying drawings are to be interpreted in an illustrative and non-limiting sense.

What the invention claimed is:

1. A method for fabricating a flip chip GaN LED, comprising:
(A) providing a GaN LED epitaxial layer;
(B) etching the GaN LED epitaxial layer to form a first groove and expose a portion of a substrate;
(C) etching the GaN LED epitaxial layer to form a plurality of second grooves adjacent to a first groove and an outer side to expose a portion of an N type GaN Ohm contacting layer;
(D) forming a translucent conducting layer over the surface of the GaN LED epitaxial layer;
(E) forming a P type electrode pad and an N type electrode pad over a surface of the translucent conducting layer;
(F) forming a first isolation protection layer over the P type electrode pad, the N type electrode pad, the first groove and the second groove;
(G) forming a metallic reflection layer over a sidewall adjacent to the P type electrode pad and corresponding to the translucent conducting layer; and
(H) forming a second isolation protection layer over a surface of the first isolation protection layer and the metallic reflection layer.

2. The method for fabricating a flip chip GaN LED according to claim 1, wherein said second protection layer is formed by grinding, drawing line, breaking and straining by a bead optical characteristic to produce individual GaN LED bead.

3. The method for fabricating a flip chip GaN LED according to claim 1, wherein the individual GaN LED bead is flipped over the heat conducting substrate with the conducting gel.

4. The method for fabricating a flip chip GaN LED according to claim 3, wherein said P type electrode pad and said N type electrode pad of the flip chip LED are securely positioned on a positive welding pad and a negative welding pad of said heat conducting substrate.

5. The method for fabricating a flip chip GaN LED according to claim 3, wherein said conducting gel can be selected from a group consisting of a silver gel, tin ball or a tin paste.

6. The method for fabricating a flip chip GaN LED according to claim 1, wherein the step for forming said first and second grooves includes dry etching and wet etching.

7. The method for fabricating a flip chip GaN LED according to claim 1, wherein said GaN LED epitaxial layer comprises an N type GaN Ohm contacting layer, a light emitting layer and a P type GaN Ohm contacting layer.

8. The method for fabricating a flip chip GaN LED according to claim 1, wherein said first groove has a U shape or a V shape.

9. The method for fabricating a flip chip GaN LED according to claim 1, wherein said second groove has a U shape or a V shape.

10. The method for fabricating a flip chip GaN LED according to claim 1, wherein said first groove is etched deeper than said second groove.

11. The method for fabricating a flip chip GaN LED according to claim 1, wherein said N type electrode pad extends to a surface of said N type GaN Ohm contacting layer.

12. The method for fabricating a flip chip GaN LED according to claim 1, wherein said first isolation protection layer has a full coverage at inner sides of said first and second grooves.

13. The method for fabricating a flip chip GaN LED according to claim 1, wherein a material of said metallic reflection layer is selected from a group consisting of silver, aluminum or rhodium.

14. The method for fabricating a flip chip GaN LED according to claim 1, wherein a material of said metallic reflection layer is selected from a combination of silver and aluminum, or nickel, platinum, beryllium, titanium and chromium.

15. The method for fabricating a flip chip GaN LED according to claim 1, wherein said translucent conducting layer is selected from a group consisting of indium oxide (In₂O₃), tin oxide (SnO₂), indium molybdenum oxides (IMO), zinc oxide (ZnO), indium zinc oxide (IZO), cellium indium oxide (CeIn₂O₃), indium tin oxides (ITO), a dual structure of nickel (Ni) and gold (Au), a dual structure of platinum (Pt) and gold, a dual structure of beryllium (Be) and gold.

16. The method for fabricating a flip chip GaN LED according to claim 1, wherein said first isolation protection layer or the second protection layer is selected from a consisting of silicon oxide (SiO₂), silicon nitride (Si₃N₄), liquefied glass, Teflon, the polyimide (Pi), aluminum oxide (Al₂O₃), titanium oxide (TiO), tantalum oxide (Ta₂O₅), yttrium oxide (Y₂O₃) or diamond film.

17. The method for fabricating a flip chip GaN LED according to claim 1, wherein said P type electrode pad, said N type electrode pad is selected from a combination of titanium and gold, titanium and aluminum, chromium and gold, or chromium and aluminum.
